(19) United States
(12) Patent Application Publication
(10) Pub. No.: US 2026/0250549 A1
(43) Pub. Date: Aug. 27, 2026

(54) SLURRY AND POLISHING METHOD

(71) Applicant: Resonac Corporation, Minato-ku, Tokyo (JP)

(72) Inventors: Masanori MAEDA, Minato-ku, Tokyo (JP); Makoto MIZUTANI, Minato-ku, Tokyo (JP)

(21) Appl. No.: 18/857,352

(22) PCT Filed: Aug. 25, 2023
(86) PCT No.: PCT/JP2023/030756

§ 371 Date: Oct. 16, 2024

(51) Int. Cl. C09G 1/02; H10P 52/40

(52) U.S. Cl. CPC C09G 1/02; H10P 52/407

(57) ABSTRACT

A slurry containing abrasive grains and water, in which the abrasive grains include cerium oxide particles, a crystallite diameter of the cerium oxide particles is 17.0 nm or more, and a lattice distortion of the cerium oxide particles is 0.10% or more.

### TECHNICAL FIELD

The present disclosure relates to a slurry, a polishing method, and the like.

### BACKGROUND ART

In recent years, processing techniques for densification and micronization are becoming more important in manufacturing steps for semiconductor elements. A CMP (chemical mechanical polishing) technique that is one of the processing techniques has become an essential technique in manufacturing steps for semiconductor elements, for formation of a shallow trench isolation (hereinafter, referred to as “STI”), flattening of pre-metal insulating materials or interlayer insulating materials, formation of plugs or embedded metal wirings, or the like.

Examples of the most frequently used polishing liquid include a silica-based polishing liquid containing silica (silicon oxide) particles such as fumed silica or colloidal silica as abrasive grains. The silica-based polishing liquid is characterized by being high in versatility, and can polish broad types of materials irrespective of insulating materials and conductive materials by appropriately selecting an abrasive grain content, a pH, additives, or the like.

On the other hand, a demand for a cerium oxide-based polishing liquid containing cerium oxide particles as abrasive grains is expanding.

For example, the cerium oxide-based polishing liquid can polish an insulating material at a high rate even when a content of abrasive grains is lower than that in the silica-based polishing liquid (for example, see Patent Literatures 1 and 2).

### CITATION LIST

### Patent Literature

Patent Literature 1: Japanese Unexamined Patent Publication No. H10-106994
Patent Literature 2: Japanese Unexamined Patent Publication No. H08-022970

### SUMMARY OF INVENTION

### Technical Problem

Meanwhile, in recent years, a 3D-NAND device in which a cell portion of the device is stacked in a vertical direction has emerged. In the present technique, a step height of the insulating materials during cell formation is several times higher compared to the conventional planar type. According to this, in order to maintain the throughput of the device manufacturing, it is necessary to rapidly eliminate the high step height as described above in a CMP step or the like, and it is necessary to improve a polishing rate for the insulating material.

An aspect of the present disclosure is to provide a slurry capable of obtaining a high polishing rate for an insulating material. Another aspect of the present disclosure is to provide a polishing method using such a slurry.

### Solution to Problem

The present disclosure relates to the following [1] to [8] and the like in some aspects.
[1] A slurry containing abrasive grains and water, in which the abrasive grains include cerium oxide particles, a crystallite diameter of the cerium oxide particles is 17.0 nm or more, and a lattice distortion of the cerium oxide particles is 0.10% or more.
[2] The slurry according to [1], in which the crystallite diameter of the cerium oxide particles is 17.0 to 40.0 nm, and the lattice distortion of the cerium oxide particles is 0.10 to 0.75%.
[3] The slurry according to [1] or [2], in which the crystallite diameter of the cerium oxide particles is 17.0 nm or more and less than 30.0 nm.
[4] The slurry according to any one of [1] to [3], in which an average particle diameter of the abrasive grains is 200 to 400 nm.
[5] The slurry according to any one of [1] to [4], in which a content of the abrasive grains is 0.01 to 10.00 mass %.
[6] The slurry according to any one of [1] to [5], in which a pH is 1.00 to 7.00.
[7] The slurry according to any one of [1] to [6], in which the slurry is used for polishing a surface to be polished containing silicon oxide.
[8] A polishing method including a step of polishing a surface to be polished using the slurry according to any one of [1] to [7].

### Advantageous Effects of Invention

According to an aspect of the present disclosure, it is possible to provide a slurry capable of obtaining a high polishing rate for an insulating material. According to another aspect of the present disclosure is to provide a polishing method using such a slurry.

### DESCRIPTION OF EMBODIMENTS

Hereinafter, embodiments of the present disclosure will be described in detail.

### Definitions

In the present specification, a numerical range indicated using “to” indicates a range including numerical values described before and after “to” as a minimum value and a maximum value, respectively. “A or more” of a numerical range means A and a range exceeding A. “A or less” of a numerical range means A and a range less than A. In a numerical range described stepwise in the present specification, an upper limit value or a lower limit value of a numerical range of a certain stage can be arbitrarily combined with an upper limit value or a lower limit value of a numerical range of another stage. In a numerical range described in the present specification, the upper limit value or the lower limit value of the numerical range may be replaced with a value shown in Examples. “A or B” may include either A or B, and may include both A and B. The materials exemplified in the present specification can be used alone or in combination of two or more thereof unless otherwise specified. When a plurality of materials corresponding to the respective components are present in the composition, a content of each component in the composition means the total amount of the plurality of materials present in the composition unless otherwise specified. The term “film” includes not only a structure having a shape formed on the entire surface but also a structure having a shape formed on a part thereof when observed as a plan view. The term “step” includes not only an independent step but also a step that cannot be clearly distinguished from other steps as long as the intended action of the step is achieved.

As described below, a slurry of the present embodiment contains abrasive grains. The abrasive grain is also referred to as an “abrasive particle”, and is referred to as an “abrasive grain” in the present specification. The abrasive grains are generally solid particles, and it is considered that an object to be removed is removed by a mechanical action of the abrasive grains and a chemical action of the abrasive grains (mainly the surfaces of the abrasive grains) at the time of polishing, but the present disclosure is not limited thereto.

### <Slurry>

A slurry of the present embodiment contains abrasive grains and water. The slurry of the present embodiment can be used as, for example, a polishing liquid (CMP polishing liquid). In the present specification, the “polishing liquid” is defined as a composition that comes into contact with a surface to be polished during polishing. The phrase “polishing liquid” itself does not limit all the components contained in the polishing liquid.

In the slurry of the present embodiment, the abrasive grains include cerium oxide particles, a crystallite diameter of the cerium oxide particles is 17.0 nm or more, and a lattice distortion of the cerium oxide particles is 0.10% or more.

According to the slurry of the present embodiment, a high polishing rate for an insulating material can be obtained, and for example, a high polishing rate for silicon oxide can be obtained. According to the slurry of the present embodiment, for example, 1700 nm/min or more (preferably, 1750 nm/min or more, 1800 nm/min or more, 1900 nm/min or more, 2000 nm/min or more, or the like) can be obtained as a polishing rate of polishing for 20 seconds in an evaluation method described in Examples described below.

When a high step height of the insulating materials (for example, silicon oxide) is quickly eliminated by using a slurry as a cerium oxide-based polishing liquid, a polishing rate decreases as polishing progresses, resulting in a problem that the time required to eliminate the step height increases. Therefore, both the high initial polishing rate and the retainability of the polishing rate are required for the slurry for eliminating the high step height. According to a mode of the slurry of the present embodiment, it is possible to suppress a reduction in polishing rate with the progress of polishing while obtaining a high polishing rate for the insulating material, and for example, it is possible to suppress a reduction in polishing rate with the progress of polishing while obtaining a high polishing rate for silicon oxide. According to a mode of the slurry of the present embodiment, for example, more than 75.0% (preferably, 75.3% or more, 80.0% or more, 85.0% or more, 88.0% or more, 90.0% or more, 95.0% or more, 98.0% or more, or the like) can be obtained as a retention rate of the polishing rate (polishing rate of polishing for 50 seconds/polishing rate of polishing for 20 seconds) in the evaluation method described in Examples described below.

A factor capable of suppressing a reduction in polishing rate with the progress of polishing while obtaining a high polishing rate for the insulating material is not necessarily clear, but is presumed to be as follows. However, the factor is not limited to the following content.

That is, when the crystallite diameter is large, the number of grain boundaries is small, and the particles are hardly broken with the progress of polishing, such that physical polishing performance can be maintained, but a new crystal plane having high reactivity is hardly exposed (chemical reactivity is low). On the other hand, when the lattice distortion is large, with the progress of polishing, the particles are easily cracked starting from the distortion, and a new crystal plane having high reactivity is easily exposed (chemical reactivity is high). Therefore, it is presumed that, when the crystallite diameter and the lattice distortion simultaneously satisfy the specific ranges described above, the chemical reactivity of the abrasive grains can be enhanced while maintaining the physical polishing performance, and both the polishing rate for the insulating material and the retainability of the polishing rate can be preferably achieved.

According to a mode of the slurry of the present embodiment, for example, 1300 nm/min or more (preferably, 1400 nm/min or more, 1500 nm/min or more, 1600 nm/min or more, 1700 nm/min or more, or the like) can be obtained as a polishing rate of polishing for 50 seconds in an evaluation method described in Examples described below.

According to the present embodiment, it is possible to provide a method for adjusting a polishing rate by adjusting a polishing rate based on the crystallite diameter and the lattice distortion of the cerium oxide particles, and it is possible to provide a method for adjusting a retention rate of a polishing rate by adjusting a retention rate of a polishing rate based on the crystallite diameter and the lattice distortion of the cerium oxide particles. According to the present embodiment, it is possible to provide a method for selecting abrasive grains, the method including selecting abrasive grains including cerium oxide particles based on the crystallite diameter and the lattice distortion of the cerium oxide particles. According to the present embodiment, it is possible to provide a use of a slurry for polishing a surface to be polished containing an insulating material, and it is possible to provide a use of a slurry for polishing a surface to be polished containing silicon oxide. According to the present embodiment, it is possible to provide a use of a slurry in a step of planarizing a base substrate surface, which is a semiconductor element manufacturing technique. According to the present embodiment, it is possible to provide a use of a slurry in a step of planarizing an STI insulating material, a pre-metal insulating material, or an interlayer insulating material.

### (Abrasive Grains)

The slurry of the present embodiment contains abrasive grains, and the abrasive grains include cerium oxide particles (particles containing cerium oxide). The cerium oxide of the cerium oxide particles may include tetravalent cerium and may include trivalent cerium.

The abrasive grains may include particles different from the cerium oxide particles. Examples of the particles different from the cerium oxide particles include silicon oxide (silica) particles, aluminum oxide (alumina) particles, silicon nitride particles, zirconium oxide (zirconia: yttria-added zirconia particles or the like) particles, titanium oxide (titania) particles, yttrium oxide (yttria) particles, silicon carbide particles, diamond particles, and polymer particles.

A content of cerium oxide (cerium oxide particles) may be in the following range based on the total mass of the abrasive grains (the total mass of the abrasive grains contained in the slurry). The content of cerium oxide (cerium oxide particles) may be 20 mass % or more, 30 mass % or more, 40 mass % or more, 50 mass % or more, more than 50 mass %, 60 mass % or more, 70 mass % or more, 80 mass % or more, 90 mass % or more, 95 mass % or more, 98 mass % or more, or 99 mass % or more, from the viewpoint of easily obtaining a high polishing rate for the insulating material. The abrasive grains contained in the slurry may be substantially composed of cerium oxide (cerium oxide particles) (a content of cerium oxide (cerium oxide particles) is substantially 100 mass % based on the total mass of the abrasive grains contained in the slurry).

The cerium oxide particles can be obtained, for example, by oxidizing a cerium compound. Examples of a method for oxidizing a cerium compound include a firing method; and an oxidation method using hydrogen peroxide or the like, and a firing method may be used from the viewpoint of easily obtaining a high polishing rate for the insulating material and easily suppressing a reduction in polishing rate with the progress of polishing. Examples of the cerium compound include cerium carbonate, cerium nitrate, cerium sulfate, and cerium oxalate. From the viewpoint of easily obtaining a high polishing rate for the insulating material and the viewpoint of easily suppressing a reduction in polishing rate with the progress of polishing, the cerium compound may be cerium carbonate, and the cerium oxide particles may contain oxides derived from cerium carbonate.

Cerium carbonate for obtaining cerium oxide particles can be obtained using a natural mineral as a raw material, for example, by the following procedure. First, unnecessary gangue is removed from ore (bastnaesite ore, heavy sand, ankerite, or the like) containing a rare earth element containing at least cerium by a beneficiation treatment to obtain rare earth concentrate (bastnaesite concentrate, monazite concentrate, Chinese complex concentrate, or the like). Next, the rare earth concentrate is subjected to a chemical treatment (alkali decomposition, sulfuric acid decomposition, hydroxide fractionation precipitation method, or the like) to reduce insoluble components such as impurities, and then the rare earth elements (neodymium or the like) are reduced by solvent extraction as necessary, thereby obtaining a cerium-containing rare earth salt solution. Then, cerium carbonate can be obtained by mixing this cerium-containing rare earth salt solution with sodium carbonate. Such a method for producing cerium carbonate is defined as an “extraction method” for the sake of convenience.

Another cerium salt (cerium nitrate, cerium sulfate, cerium oxalate, or the like) can be synthesized by changing the above-described sodium carbonate used in the “extraction method” to another salt. For example, cerium nitrate (for example, cerium (III) nitrate) is obtained by mixing a cerium-containing rare earth salt solution and sodium nitrate. Cerium carbonate can be obtained by reacting an aqueous solution of a cerium salt with a solution of a precursor having a carbonyl group. For example, cerium carbonate can be precipitated by reacting an aqueous solution of cerium nitrate (for example, cerium (III) nitrate) with a solution of a precursor having a carbonyl group at a temperature of 80 to 100° C. As the precursor having a carbonyl group, urea or the like can be used. Such a method for producing cerium carbonate is defined as a “carbonyl substitution method” for the sake of convenience. From the viewpoint of easily obtaining a high polishing rate for the insulating material and the viewpoint of easily suppressing a reduction in polishing rate with the progress of polishing, the method for producing cerium carbonate of the present embodiment may be either the “extraction method” or the “carbonyl substitution method” and may be the “carbonyl substitution method”.

In the slurry of the present embodiment, the crystallite diameter of the cerium oxide particles is 17.0 nm or more, and the lattice distortion of the cerium oxide particles is 0.10% or more. The crystallite diameter and the lattice distortion can be derived by applying Williamson-Hall method to the data obtained by powder X-ray diffraction (XRD) of the cerium oxide particles. In the Williamson-Hall method, sin θ is plotted on the horizontal axis and β cos θ (β=integration width) is plotted on the vertical axis for all peaks of an X-ray diffraction pattern (XRD chart) obtained by XRD. An approximate straight line of a linear function is created for the plotted points by the least squares method, a crystallite diameter is obtained from the intercept of the approximate straight line, and a lattice distortion is obtained from the slope of the approximate straight line. A commercially available analysis software for XRD may be used, and for example, “PDXL2” manufactured by Rigaku Corporation can be used to derive the crystallite diameter and the lattice distortion.

When the crystallite diameter of the cerium oxide particles is 17.0 nm or more, it is presumed that the physical strength of the cerium oxide particles is increased, and the polishing rate for the insulating material and the retainability of the polishing rate are improved. When the lattice distortion of the cerium oxide particles is 0.10% or more, it is presumed that the chemical reactivity of the cerium oxide particles is enhanced, and the polishing rate for the insulating material and the retainability of the polishing rate are improved.

The crystallite diameter of the cerium oxide particles may be 18.0 nm or more, 19.0 nm or more, 20.0 nm or more, 22.0 nm or more, 23.0 nm or more, 24.0 nm or more, or 25.0 nm or more, from the viewpoint of easily increasing the physical strength of the cerium oxide particles and easily improving the polishing rate for the insulating material and the retainability of the polishing rate. The crystallite diameter of the cerium oxide particles may be 28.0 nm or more, 30.0 nm or more, or 32.0 nm or more, from the viewpoint of easily improving the retainability of the polishing rate. The crystallite diameter of the cerium oxide particles may be 60.0 nm or less, 58.0 nm or less, 55.0 nm or less, 53.0 nm or less, 50.0 nm or less, less than 50.0 nm, 45.0 nm or less, 40.0 nm or less, less than 40.0 nm, 38.0 nm or less, 37.0 nm or less, 36.0 nm or less, 35.0 nm or less, or 33.0 nm or less, from the viewpoint of easily improving the chemical reactivity of the cerium oxide particles and easily improving the polishing rate for the insulating material and the retainability of the polishing rate. The crystallite diameter of the cerium oxide particles may be 32.0 nm or less, 30.0 nm or less, less than 30.0 nm, or 28.0 nm or less, from the viewpoint of easily improving the polishing rate for the insulating material. The crystallite diameter of the cerium oxide particles may be 25.0 nm or less, 24.0 nm or less, 23.0 nm or less, 22.0 nm or less, or 20.0 nm or less. From these viewpoints, the crystallite diameter of the cerium oxide particles may be 17.0 to 60.0 nm, 17.0 to 40.0 nm, 17.0 to 35.0 nm, 17.0 to 30.0 nm, 17.0 nm or more and less than 30.0 nm, 20.0 to 60.0 nm, 20.0 to 40.0 nm, 20.0 to 35.0 nm, 20.0 to 30.0 nm, 20.0 nm or more and less than 30.0 nm, 25.0 to 60.0 nm, 25.0 to 40.0 nm, 25.0 to 35.0 nm, 25.0 to 30.0 nm, 25.0 nm or more and less than 30.0 nm, 22.0 to 38.0 nm, 23.0 to 37.0 nm, or 24.0 to 36.0 nm.

The lattice distortion of the cerium oxide particles may be 0.11% or more, 0.12% or more, 0.15% or more, 0.17% or more, 0.20% or more, 0.25% or more, 0.26% or more, 0.30% or more, 0.40% or more, 0.50% or more, 0.60% or more, or 0.70% or more, from the viewpoint of easily improving the atomic density of the cerium oxide particles and easily improving the polishing rate for the insulating material and the retainability of the polishing rate. The lattice distortion of the cerium oxide particles may be 1.00% or less, 0.90% or less, 0.80% or less, 0.75% or less, 0.70% or less, 0.60% or less, 0.50% or less, 0.40% or less, 0.30% or less, 0.26% or less, 0.25% or less, 0.20% or less, 0.17% or less, 0.15% or less, 0.12% or less, or 0.11% or less, from the viewpoint of easily improving the crystallinity of the cerium oxide particles and easily improving the polishing rate for the insulating material and the retainability of the polishing rate. From these viewpoints, the lattice distortion of the cerium oxide particles may be 0.10 to 1.00%, 0.11 to 1.00%, 0.15 to 1.00%, 0.20 to 1.00%, 0.30 to 1.00%, 0.10 to 0.75%, 0.11 to 0.75%, 0.15 to 0.75%, 0.20 to 0.75%, 0.30 to 0.75%, 0.10 to 0.30%, 0.11 to 0.30%, 0.15 to 0.30%, 0.20 to 0.30%, 0.10 to 0.20%, 0.11 to 0.20%, 0.15 to 0.20%, 0.10 to 0.15%, 0.11 to 0.15%, or 0.10 to 0.11%.

The above-described numerical range of the crystallite diameter of the cerium oxide particles can be arbitrarily combined with the above-described numerical range of the lattice distortion of the cerium oxide particles. For example, the slurry of the present embodiment may have a mode in which the crystallite diameter of the cerium oxide particles is 17.0 to 40.0 nm and the lattice distortion of the cerium oxide particles is 0.10 to 0.75%.

Examples of a method for adjusting the crystallite diameter and the lattice distortion of the cerium oxide particles include a method of changing a composition of a raw material; a method of changing a raw material preparation method; a method of changing a firing temperature, a firing time, or the like in a firing method; and a method of changing a method, conditions, or the like of pulverization. These methods may be used alone or in combination.

The cerium oxide particles to be measured by the XRD measurement for obtaining the crystallite diameter and the lattice distortion of the cerium oxide particles may be recovered by drying (drying and solidifying) the slurry, and may be recovered by separating and removing components other than the cerium oxide particles from the dried product. When the crystallite diameter and the lattice distortion of the cerium oxide particles do not vary in preparation of the slurry, the cerium oxide particles to be measured by the XRD measurement may be cerium oxide particles before being mixed with other components such as water.

An average particle diameter of the abrasive grains or an average particle diameter of the cerium oxide particles may be in the following range. From the viewpoint of easily obtaining a high polishing rate for the insulating material, the average particle diameter may be 100 nm or more, 150 nm or more, 175 nm or more, more than 175 nm, 180 nm or more, 200 nm or more, 220 nm or more, 230 nm or more, 240 nm or more, 245 nm or more, 250 nm or more, 255 nm or more, 260 nm or more, 265 nm or more, 270 nm or more, 275 nm or more, or 280 nm or more. From the viewpoint of easily reducing scratches caused by polishing, the average particle diameter may be 600 nm or less, 550 nm or less, less than 550 nm, 500 nm or less, 450 nm or less, 400 nm or less, 350 nm or less, 320 nm or less, 300 nm or less, 295 nm or less, 290 nm or less, 285 nm or less, 280 nm or less, 275 nm or less, 270 nm or less, 265 nm or less, 260 nm or less, 255 nm or less, or 250 nm or less. From these viewpoints, the average particle diameter may be 100 to 600 nm, 100 to 500 nm, 100 to 400 nm, 100 to 300 nm, 100 to 280 nm, 200 to 600 nm, 200 to 500 nm, 200 to 400 nm, 200 to 300 nm, 200 to 280 nm, 250 to 600 nm, 250 to 500 nm, 250 to 400 nm, 250 to 300 nm, 250 to 280 nm, 270 to 600 nm, 270 to 500 nm, 270 to 400 nm, 270 to 300 nm, or 270 to 280 nm.

The average particle diameter means a value of a MV (volume average diameter) measured by a laser diffraction particle diameter distribution meter, and can be measured, for example, by a method described in Examples described below. The measurement of the average particle diameter (volume average diameter) may be performed by diluting the slurry with water to adjust the content of the abrasive grains or the content of the cerium oxide particles to an appropriate content, and for example, in the case of the trade name “SYNC” manufactured by MicrotracBEL Corp., the content may be adjusted to a DV (diffraction volume) value of 0.0010 to 0.0150. The DV value is a concentration index using the total amount of scattered light from the sample received by the detector, and tends to increase as the content of abrasive grains or the content of cerium oxide particles in the sample increases. In a case where a slurry containing abrasive grains (abrasive grains including cerium oxide particles), additives, and water is stored separately in a first liquid containing the abrasive grains and water and a second liquid containing the additives and water, a content of the abrasive grains may be adjusted to an appropriate content by diluting the first liquid with water, and an average particle diameter may be measured.

Examples of a method for adjusting the average particle diameter include adjustment of a composition, a preparation method, a firing temperature, a firing time, and the like of a raw material; pulverization; classification; and filtration. The pulverization, classification, and filtration may be performed on the abrasive grains or the cerium oxide particles, and may be performed on the raw material (cerium compound such as cerium carbonate) for obtaining cerium oxide particles.

The content of the abrasive grains in the slurry may be in the following range based on the total mass of the slurry. The content of the abrasive grains may be 0.01 mass % or more, 0.05 mass % or more, 0.10 mass % or more, 0.15 mass % or more, 0.30 mass % or more, 0.50 mass % or more, 0.80 mass % or more, 1.00 mass % or more, 1.20 mass % or more, 1.50 mass % or more, 1.80 mass % or more, or 2.00 mass % or more, from the viewpoint of easily obtaining a high polishing rate for the insulating material. The content of the abrasive grains may be 20.00 mass % or less, 15.00 mass % or less, 10.00 mass % or less, 8.00 mass % or less, 5.00 mass % or less, 4.50 mass % or less, 4.00 mass % or less, 3.50 mass % or less, 3.00 mass % or less, 2.50 mass % or less, or 2.00 mass % or less, from the viewpoint that aggregation of the particles is suppressed and the surface to be polished is hardly scratched. From these viewpoints, the content of the abrasive grains may be 0.01 to 20.00 mass %, 0.01 to 10.00 mass %, 0.01 to 5.00 mass %, 0.10 to 20.00 mass %, 0.10 to 10.00 mass %, 0.10 to 5.00 mass %, 0.50 to 20.00 mass %, 0.50 to 10.00 mass %, 0.50 to 5.00 mass %, 1.00 to 20.00 mass %, 1.00 to 10.00 mass %, or 1.00 to 5.00 mass %.

### (Water)

Water is not particularly limited, and examples thereof include deionized water and ultrapure water. A content of water may be a remainder of the slurry excluding the content of other constituent components, and is not particularly limited.

The content of water in the slurry may be in the following range based on the total mass of the slurry from the viewpoint of easily suppressing a reduction in polishing rate with the progress of polishing while obtaining a high polishing rate for the insulating material. The content of water may be 50 mass % or more, 70 mass % or more, 80 mass % or more, 90 mass % or more, 93 mass % or more, 95 mass % or more, 96 mass % or more, or 97 mass % or more. The content of water may be less than 100 mass %, 99 mass % or less, or 98 mass % or less. From these viewpoints, the content of water may be 50 mass % or more and less than 100 mass %, 50 to 99 mass %, 50 to 98 mass %, 80 mass % or more and less than 100 mass %, 80 to 99 mass %, 80 to 98 mass %, 90 mass % or more and less than 100 mass %, 90 to 99 mass %, or 90 to 98 mass %.

### (Additive)

The slurry of the present embodiment may contain an optional additive and may not contain an optional additive. Examples of the optional additive include a polar solvent (ethanol, acetone, or the like), a material having a carboxyl group (excluding a compound corresponding to a polyoxyalkylene compound or a water-soluble polymer), a polyoxyalkylene compound, a water-soluble polymer, an oxidant (for example, hydrogen peroxide), and a dispersant (for example, a phosphoric acid-based inorganic salt).

Examples of the material having a carboxyl group include monocarboxylic acids such as acetic acid, propionic acid, butyric acid, and valeric acid; hydroxy acids such as lactic acid, malic acid, and citric acid; dicarboxylic acids such as malonic acid, succinic acid, fumaric acid, and maleic acid; and amino acids such as arginine, histidine, and lysine.

Examples of the polyoxyalkylene compound include a polyalkylene glycol and a polyoxyalkylene derivative.

Examples of the polyalkylene glycol include polyethylene glycol, polypropylene glycol, and polybutylene glycol.

The polyoxyalkylene derivative is, for example, a compound obtained by introducing a functional group or a substituent into a polyalkylene glycol, or a compound obtained by adding a polyalkylene oxide to an organic compound. Examples of the functional group or the substituent include an alkyl ether group, an alkyl phenyl ether group, a phenyl ether group, a styrenated phenyl ether group, a glyceryl ether group, an alkyl amine group, a fatty acid ester group, and a glycol ester group. Examples of the polyoxyalkylene derivative include polyoxyethylene alkyl ether, polyoxyethylene bisphenol ether (for example, BA Glycol series, manufactured by Nippon Nyukazai Co., Ltd.), polyoxyethylene styrenated phenyl ether (for example, EMULGEN series, manufactured by Kao Corporation), polyoxyethylene alkylphenyl ether (for example, NOIGEN EA series, manufactured by DKS Co. Ltd.), polyoxyalkylene polyglyceryl ether (for example, SC-E series and SC-P series, manufactured by Sakamoto Yakuhin Kogyo Co., Ltd.), polyoxyethylene sorbitan fatty acid ester (for example, SORGEN TW series, manufactured by DKS Co. Ltd.), polyoxyethylene fatty acid ester (for example, EMANON series, manufactured by Kao Corporation), polyoxyethylene alkylamine (for example, AMILADIN D, manufactured by DKS Co. Ltd.), and other compounds to which a polyalkylene oxide is added (for example, SURFYNOL 465, manufactured by Nissin Chemical Industry Co., Ltd.; and TMP series, manufactured by Nippon Nyukazai Co., Ltd.).

The water-soluble polymer has an effect of adjusting dispersion stability of the abrasive grains, and the like. The “water-soluble polymer” is defined as a polymer that dissolves in an amount of 0.1 g or more in 100 g of water. A polymer corresponding to the polyoxyalkylene compound described above is not included in the “water-soluble polymer”.

Examples of the water-soluble polymer include polycarboxylic acids such as polyacrylic acid and polymaleic acid; acrylic polymers such as polyacrylamide and polydimethylacrylamide; polysaccharides such as carboxymethylcellulose, agar, curdlan, dextrin, cyclodextrin, and pullulan; vinyl-based polymers such as polyvinyl alcohol, polyvinyl pyrrolidone, and polyacrolein; and glycerin-based polymers such as polyglycerin and a polyglycerin derivative.

A content of the water-soluble polymer may be in the following range based on the total mass of the slurry from the viewpoint of easily obtaining the addition effect of the water-soluble polymer while suppressing sedimentation of the abrasive grains. The content of the water-soluble polymer may be 0.001 mass % or more, 0.005 mass % or more, 0.010 mass % or more, 0.020 mass % or more, 0.030 mass % or more, 0.040 mass % or more, 0.050 mass % or more, 0.060 mass % or more, 0.070 mass % or more, or 0.075 mass % or more. The content of the water-soluble polymer may be 10.000 mass % or less, 8.000 mass % or less, 6.000 mass % or less, 5.000 mass % or less, 3.000 mass % or less, 1.000 mass % or less, 0.500 mass % or less, 0.300 mass % or less, 0.100 mass % or less, 0.080 mass % or less, or 0.075 mass % or less. From these viewpoints, the content of the water-soluble polymer may be 0.001 to 10.000 mass %, 0.001 to 1.000 mass %, 0.001 to 0.500 mass %, 0.001 to 0.100 mass %, 0.010 to 10.000 mass %, 0.010 to 1.000 mass %, 0.010 to 0.500 mass %, 0.010 to 0.100 mass %, 0.030 to 10.000 mass %, 0.030 to 1.000 mass %, 0.030 to 0.500 mass %, 0.030 to 0.100 mass %, 0.050 to 10.000 mass %, 0.050 to 1.000 mass %, 0.050 to 0.500 mass %, or 0.050 to 0.100 mass %.

(pH)

A pH of the slurry of the present embodiment may be in the following range. The pH may be 1.00 or more, 1.50 or more, 2.00 or more, 2.50 or more, 3.00 or more, more than 3.00, 3.50 or more, more than 3.50, 4.00 or more, more than 4.00, 4.10 or more, 4.20 or more, 4.30 or more, 4.40 or more, 4.50 or more, more than 4.50, 4.60 or more, 4.70 or more, or 4.80 or more, from the viewpoint of easily obtaining a high polishing rate for the insulating material. The pH may be 7.00 or less, less than 7.00, 6.50 or less, less than 6.50, 6.00 or less, less than 6.00, 5.50 or less, less than 5.50, 5.00 or less, less than 5.00, 4.90 or less, 4.85 or less, 4.80 or less, 4.75 or less, 4.70 or less, 4.65 or less, 4.60 or less, 4.55 or less, 4.50 or less, less than 4.50, 4.45 or less, 4.40 or less, 4.35 or less, 4.30 or less, 4.25 or less, or 4.20 or less, from the viewpoint of easily improving the storage stability of the slurry. From these viewpoints, the pH may be 1.00 to 7.00, 1.00 to 6.00, 1.00 to 5.00, 1.00 to 4.50, 2.00 to 7.00, 2.00 to 6.00, 2.00 to 5.00, 2.00 to 4.50, 3.00 to 7.00, 3.00 to 6.00, 3.00 to 5.00, 3.00 to 4.50, 4.00 to 7.00, 4.00 to 6.00, 4.00 to 5.00, or 4.00 to 4.50. The pH of the slurry is defined as the pH at a liquid temperature of 25° C.

The pH of the slurry can be adjusted by an acid component such as an inorganic acid or an organic acid; an alkaline component such as ammonia, sodium hydroxide, tetramethylammonium hydroxide (TMAH), imidazole, or alkanolamine; or the like. In order to stabilize the pH, a buffering agent may be added, and a buffer solution (a liquid containing a buffering agent) may be added. Examples of the buffer solution include an acetate buffer solution and a phthalate buffer solution.

The pH of the slurry of the present embodiment can be measured with a pH meter (for example, model number PHL-40, manufactured by DKK-TOA CORPORATION). For example, after a pH meter is calibrated at two points using a phthalate pH buffer solution (pH: 4.01) and a neutral phosphate pH buffer solution (pH: 6.86) as standard buffer solutions, an electrode of the pH meter is placed in the slurry, and a value after stabilization for 2 minutes or longer can be measured as the pH of the slurry. Liquid temperatures of the standard buffer solution and the slurry are both 25° C.

### (Storage Mode)

When the slurry of the present embodiment contains the optional additive described above, the slurry of the present embodiment may be stored in a one-liquid state containing abrasive grains, an additive, and water, and may be stored as a set of a plurality of liquids (for example, two liquids) in which constituent components of the slurry are divided into a first liquid containing abrasive grains and water and a second liquid containing an additive and water so that the first liquid and the second liquid are mixed to form a slurry. The slurry of the present embodiment may be in a one-liquid state containing abrasive grains, an additive, and water, and may be the first liquid in the plurality of liquid sets. The second liquid may contain at least one of the additive, and the first liquid may contain an additive of the same types as or different types from the additive of the second liquid. The constituent components of the slurry may be stored in three or more liquids.

In the plurality of liquid sets described above, the first liquid and the second liquid are mixed immediately before polishing or during polishing to prepare a slurry. The one-liquid slurry may be stored as a storage liquid in which a content of water is reduced, and may be used by being diluted with water at the time of polishing. In the plurality of liquid sets, the first liquid and the second liquid may be stored as a storage liquid in which a content of water is reduced, and may be used by being diluted with water at the time of polishing.

### <Polishing Method>

A polishing method of the present embodiment (a polishing method of a base substrate or the like) includes a polishing step of polishing a surface to be polished (a surface to be polished of a base substrate or the like) using the slurry of the present embodiment. The slurry in the polishing step may be a slurry obtained by mixing the first liquid and the second liquid of the plurality of liquid sets described above.

In the polishing step, for example, the slurry of the present embodiment may be supplied between a material to be polished and a polishing pad in a state where an insulating material of a base substrate having the insulating material is pressed against the polishing pad (polishing cloth) of a polishing platen, and a surface to be polished of the insulating material may be polished by relatively moving the base substrate and the polishing platen. In the polishing step, for example, at least a part of the insulating material is removed by polishing.

Examples of an object to be polished include a base substrate to be polished. Examples of the substrate to be polished include a base substrate in which an insulating material is formed on a substrate (for example, a semiconductor substrate on which an STI pattern, a gate pattern, a wiring pattern, or the like are formed) related to semiconductor element manufacturing. Examples of the insulating material include silicon oxide. The insulating material may be a single material and may be a plurality of materials. When a plurality of materials are exposed on a surface to be polished, these materials can be regarded as insulating materials. The insulating material may be a film-like (insulating film) and may be a silicon oxide film.

By polishing the insulating material (for example, silicon oxide) formed on the substrate using the slurry of the present embodiment to remove an excess portion, irregularities formed on the surface of the insulating material are eliminated, and a smooth surface can be obtained over the entire surface of the insulating material.

In the polishing method of the present embodiment, a general polishing apparatus having a holder capable of holding a base substrate having a surface to be polished and a polishing platen to which a polishing pad can be attached can be used as a polishing apparatus. A motor or the like capable of changing a rotational speed may be attached to each of the holder and the polishing platen.

As the polishing pad, a general non-woven fabric, foam, non-foam, or the like can be used. As a material of the polishing pad, a resin such as polyurethane, an acrylic resin, polyester, an acryl-ester copolymer, polytetrafluoroethylene, polypropylene, polyethylene, poly 4-methylpentene, cellulose, cellulose ester, polyamide (for example, Nylon (trade name) and aramid), polyimide, polyimide-amide, a polysiloxane copolymer, an oxirane compound, a phenolic resin, polystyrene, polycarbonate, or an epoxy resin can be used. The material of the polishing pad may be at least one selected from the group consisting of foamed polyurethane and non-foamed polyurethane from the viewpoint of easily obtaining excellent polishing rate and flatness. The polishing pad may be subjected to grooving so that the slurry accumulates.

The polishing conditions are not limited, but an upper limit of a rotational speed of the polishing platen may be 200 min-1 (min-1=rpm) or less so that the base substrate does not jump out, and an upper limit of a polishing pressure (processing load) applied to the base substrate may be 100 kPa or less from the viewpoint of easily suppressing the occurrence of polishing scratches. During polishing, the slurry may be continuously supplied to the polishing pad by a pump or the like. The amount of the slurry supplied in this case is not limited, and the surface of the polishing pad may be always covered with the slurry.

The slurry and the polishing method of the present embodiment may be used to polish a surface to be polished containing silicon oxide. The slurry and the polishing method of the present embodiment can be suitably used for formation of STI and high-rate polishing of an interlayer insulating material. In such silicon oxide, a part of the constituent elements may be substituted with a carbon atom, a nitrogen atom, or the like.

The slurry and the polishing method of the present embodiment can also be used for polishing a pre-metal insulating material. Examples of the pre-metal insulating material include silicon oxide, phosphorus-silicate glass, boron-phosphorus-silicate glass, silicon oxyfluoride, and fluorinated amorphous carbon.

The slurry and the polishing method of the present embodiment can also be applied to a material other than the insulating material such as silicon oxide. Examples of such a material include high dielectric constant materials such as Hf-based, Ti-based, and Ta-based oxides; semiconductor materials such as silicon, amorphous silicon, SiC, SiGe, Ge, GaN, GaP, GaAs, and an organic semiconductor; phase change materials such as GeSbTe; inorganic conductive materials such as ITO; and polymer resin materials such as polyimide-based, polybenzoxazole-based, acryl, epoxy-based, and phenolic materials.

The slurry and the polishing method of the present embodiment can be applied not only to a film-like object to be polished but also to various substrates formed of glass, silicon, SiC, SiGe, Ge, GaN, GaP, GaAs, sapphire, plastic, or the like.

The slurry and the polishing method of the present embodiment can be used not only in manufacturing a semiconductor element but also in manufacturing an image display device such as a TFT or an organic EL; an optical component such as a photomask, a lens, a prism, an optical fiber, or a single crystal scintillator; an optical element such as an optical switching element or an optical waveguide; a light emitting element such as a solid laser or a blue laser LED; or a magnetic storage device such as a magnetic disk or a magnetic head.

### <Manufacturing Method and the Like>

A method for manufacturing a component of the present embodiment includes a component preparation step of obtaining a component using a base substrate (polished member) polished by the polishing method of the present embodiment. The component of the present embodiment is a component obtained by the method for manufacturing a component of the present embodiment. The component of the present embodiment is not particularly limited, but may be an electronic component (for example, a semiconductor component such as a semiconductor package), may be a wafer (for example, a semiconductor wafer), and may be a chip (for example, a semiconductor chip). As a mode of the method for manufacturing a component of the present embodiment, in a method for manufacturing an electronic component of the present embodiment, an electronic component is obtained using a base substrate polished by the polishing method of the present embodiment. As a mode of the method for manufacturing a component of the present embodiment, in a method for manufacturing a semiconductor component of the present embodiment, a semiconductor component (for example, a semiconductor package) is obtained using a base substrate polished by the polishing method of the present embodiment. The method for manufacturing a component of the present embodiment may include, before the component preparation step, a polishing step of polishing a base substrate by the polishing method of the present embodiment.

The method for manufacturing a component of the present embodiment may include, as a mode of the component preparation step, an individually dividing step of individually dividing a base substrate (polished member) polished by the polishing method of the present embodiment. The individually dividing step may be, for example, a step of dicing a wafer (for example, a semiconductor wafer) polished by the polishing method of the present embodiment to obtain a chip (for example, a semiconductor chip). As a mode of the method for manufacturing a component of the present embodiment, the method for manufacturing an electronic component of the present embodiment may include a step of obtaining an electronic component (for example, a semiconductor component) by individually dividing a base substrate polished by the polishing method of the present embodiment. As a mode of the method for manufacturing a component of the present embodiment, the method for manufacturing a semiconductor component of the present embodiment may include a step of obtaining a semiconductor component (for example, a semiconductor package) by individually dividing a base substrate polished by the polishing method of the present embodiment.

The method for manufacturing a component of the present embodiment may include, as a mode of the component preparation step, a connection step of connecting (for example, electrically connecting) a base substrate (polished member) polished by the polishing method of the present embodiment and other body to be connected. The body to be connected to the base substrate polished by the polishing method of the present embodiment is not particularly limited, may be a base substrate polished by the polishing method of the present embodiment, and may be a body to be connected different from the base substrate polished by the polishing method of the present embodiment. In the connection step, the base substrate and the body to be connected may be directly connected (connected in a state where the base substrate and the body to be connected are in contact with each other), and the base substrate and the body to be connected may be connected via other member (conductive member or the like). The connection step can be performed before the individually dividing step, after the individually dividing step, or before and after the individually dividing step.

The connection step may be a step of connecting a polished surface of the base substrate polished by the polishing method of the present embodiment and the body to be connected, and may be a step of connecting a connection surface of the base substrate polished by the polishing method of the present embodiment and a connection surface of the body to be connected. The connection surface of the base substrate may be the polished surface polished by the polishing method of the present embodiment. By the connection step, a connection body having a base substrate and a connected body can be obtained. In the connection step, when the connection surface of the base substrate has a metal portion, the body to be connected may be brought into contact with the metal portion. In the connection step, when the connection surface of the base substrate has the metal portion and the connection surface of the body to be connected has the metal portion, the metal portions may be brought into contact with each other. The metal portion may contain copper.

A device (for example, an electronic device such as a semiconductor device) of the present embodiment has at least one selected from the group consisting of a base substrate polished by the polishing method of the present embodiment and a component of the present embodiment.

### EXAMPLES

Hereinafter, the present disclosure will be specifically described with reference to Examples, but the present disclosure is not limited to the Examples below.

### Preparation of Slurry

### Comparative Example 1

Based on the “extraction method” described above, 0.1 mol/L of a cerium (III) sulfate aqueous solution and 0.1 mol/L of a sodium carbonate aqueous solution were mixed at a volume ratio of 1:2 while maintaining the temperature at 95° C. to generate a precipitate of cerium carbonate. This precipitate was filtered and dried to obtain a cerium carbonate powder (raw material). This cerium carbonate powder was placed in an alumina container, and the cerium carbonate powder was fired in the air at a firing temperature of 800° C. for 1 hour using an oven “HPM-2N” manufactured by AS ONE Corporation to obtain a white powder. Phase identification of this powder was performed by XRD, and it was confirmed that the powder was a cerium oxide powder.

This cerium oxide powder was crushed in a mortar, and then passed through a sieve with a mesh size of 450 μm to obtain a crushed product. This crushed product, pure water, and acetic acid were mixed at a mass ratio of 20.00:79.94:0.06 to obtain a mixture, and then this mixture was subjected to a pulverization treatment for 30 minutes using a wet-type pulverizing device “Star Burst Labo HJP-25005” (pressure 245 MPa) manufactured by SUGINO MACHINE LIMITED CO., LTD. to obtain a dispersion. This dispersion was centrifuged for 60 seconds using a centrifuge “himac CR7” (rotational speed: 2000 rpm) manufactured by Hitachi Koki Co., Ltd., and a dispersion containing cerium oxide particles was obtained as a liquid retained in the upper portion of the container after the centrifugation. Thereafter, the cerium oxide particles were recovered from this dispersion.

These cerium oxide particles (abrasive grains), pure water, and polyglycerin (trade name: Polyglycerin #750, manufactured by Sakamoto Yakuhin Kogyo Co., Ltd.) were mixed at a mass ratio of 2.000:97.925:0.075 to obtain a slurry for polishing.

### Example 1

Based on the “carbonyl substitution method” described above, 0.1 mol/L of a cerium (III) nitrate aqueous solution and 7.8 mol/L of a urea aqueous solution were mixed at a volume ratio of 6:1 while maintaining the temperature at 95° C. to generate a precipitate of cerium carbonate. This precipitate was filtered and dried to obtain a cerium carbonate powder (raw material). This cerium carbonate powder was placed in an alumina container, and the cerium carbonate powder was fired in the air at a firing temperature of 800° C. for 1 hour using an oven “HPM-2N” manufactured by AS ONE Corporation to obtain a white powder. Phase identification of this powder was performed by XRD, and it was confirmed that the powder was a cerium oxide powder.

This cerium oxide powder was crushed in a mortar, and then passed through a sieve with a mesh size of 450 μm to obtain a crushed product. This crushed product, pure water, and acetic acid were mixed at a mass ratio of 20.00:79.94:0.06 to obtain a mixture, and then this mixture was subjected to a pulverization treatment for 10 minutes using a wet-type pulverizing device “Star Burst Labo HJP-25005” (pressure 245 MPa) manufactured by SUGINO MACHINE LIMITED CO., LTD. to obtain a dispersion. This dispersion was centrifuged for 60 seconds using a centrifuge “himac CR7” (rotational speed: 2000 rpm) manufactured by Hitachi Koki Co., Ltd., and a dispersion containing cerium oxide particles was obtained as a liquid retained in the upper portion of the container after the centrifugation. Thereafter, the cerium oxide particles were recovered from this dispersion.

These cerium oxide particles (abrasive grains), pure water, and polyglycerin (trade name: Polyglycerin #750, manufactured by Sakamoto Yakuhin Kogyo Co., Ltd.) were mixed at a mass ratio of 2.000:97.925:0.075 to obtain a slurry for polishing.

### Example 2

A slurry for polishing was obtained in the same manner as that of Example 1, except that the firing temperature was changed to 700° C.

### Example 3

A slurry for polishing was obtained in the same manner as that of Example 1, except that the firing temperature was changed to 500° C.

### Example 4

A slurry for polishing was obtained in the same manner as that of Comparative Example 1, except that the firing temperature was changed to 700° C.

### Example 5

A slurry for polishing was obtained in the same manner as that of Comparative Example 1, except that the firing temperature was changed to 600° C.

### Comparative Example 2

A slurry for polishing was obtained in the same manner as that of Comparative Example 1, except that the firing temperature was changed to 500° C.

### <Average Particle Diameter>

An appropriate amount of each of the slurries described above was introduced into a laser diffraction particle diameter distribution meter (trade name “SYNC”, manufactured by MicrotracBEL Corp., particle refractive index: 2.20) to obtain a MV (volume average diameter) as an average particle diameter of the abrasive grains. The measurement results are shown in Table 1.

### <Crystallite Diameter and Lattice Distortion>

Each of the slurries described above was placed in a commercially available evaporating dish, and then dried in a vacuum dryer (ADP200, manufactured by Yamato Scientific Co., Ltd., 40° C., about 1000 Pa) for 24 hours to obtain a dried product. This dried product was crushed in a mortar, and then subjected to XRD measurement under the conditions below to obtain an X-ray diffraction pattern. Using “PDXL2” manufactured by Rigaku Corporation, the crystallite diameter and the lattice distortion were calculated based on the Williamson-Hall method. In the analysis, the measurement data of LaB6 was used as an external standard sample of the line width (removal of the line width derived from the device).

### [XRD Measurement Conditions]

XRD apparatus: horizontal sample type multi-purpose X-ray diffractometer Ultima IV (manufactured by Rigaku Corporation)
X-ray source: CuKα ray
Scanning mode: 2θ/θ
X-ray tube voltage: 40 kV
X-ray tube current: 40 mA
Divergence slit: 1 deg
Divergence vertical restriction slit: 10 mm
Scattering slit: 1 deg
Light receiving slit: 0.15 mm
Kβ filter: none (using counter monochromator)
Scanning range: 3 to 90 deg
Step: 0.01 deg
Scanning speed: 0.5 deg/min

### <pH of Slurry>

The pH (25° C.) of each of the slurries described above was measured using model number PHL-40 manufactured by DKK-TOA CORPORATION. The measurement results are shown in Table 1.

### <CMP Evaluation>

Using each of the slurries described above, CMP evaluation was performed under the following conditions.

### [CMP Polishing Conditions]

Polishing apparatus: Reflexion LK CMP (manufactured by Applied Materials, Inc.)
Flow rate of slurry: 250 mL/min
Substrate to be polished: As a blanket wafer on which a pattern was not formed, a substrate to be polished having a silicon oxide film having a thickness of 2 μm formed by a plasma CVD method on a silicon substrate was used.
Polishing pad: foamed polyurethane resin having independent air bubbles (model number: IK4250H, manufactured by NITTA DuPont Incorporated)
Polishing pressure: 27.6 kPa (4 psi)
Rotational speed of substrate to be polished and polishing platen:

$$substrate to be polished / polishing platen = 117 / 123 rpm$$

Polishing time: 20 seconds and 50 seconds
Wafer washing: After the CMP treatment, the wafer was washed with water while applying ultrasonic waves, and then dried with a spin dryer.

The polishing rates of polishing for 20 seconds and polishing for 50 seconds for the silicon oxide film polished and washed under the conditions described above were obtained by the equation below. The results are shown in Table 1. A film thickness difference of the silicon oxide film before and after polishing was determined using a light interference type film thickness measuring apparatus (trade name: Nova i500, manufactured by Nova LTD.)

$$Polishing rate = Film thickness difference [ nm ] of silicon oxide film before and after polishing / Polishing time [ min ]$$

Using the polishing rates of polishing for 20 seconds and polishing for 50 seconds described above, a retention rate of the polishing rate was obtained by the equation below. The results are shown in Table 1.

$$Retention rate [ \% ] of polishing rate = ( Polishing rate [ nm / min ] of polishing for 50 seconds / Polishing rate [ nm / min ] of polishing for 20 seconds ) \times 100$$

TABLE 1

| | | Comparative | | | | | | Comparative |
|---|---|---|---|---|---|---|---|---|
| | | Example | Example | | | | | Example |
| | | 1 | 1 | 2 | 3 | 4 | 5 | 2 |
| Cerium | Production | Extraction | Carbonyl | | | Extraction | | |
| oxide | method of raw | method | substitution | | | method | | |
| particles | material | | method | | | | | |
| | Firing | 800 | 800 | 700 | 500 | 700 | 600 | 500 |
| | temperature of | | | | | | | |
| | raw material | | | | | | | |
| | [° C.] | | | | | | | |
| | Average particle | 302 | 262 | 282 | 276 | 272 | 248 | 242 |
| | diameter [nm] | | | | | | | |
| | Crystallite | 58.8 | 55.5 | 32.6 | 25.7 | 24.8 | 19.5 | 16.4 |
| | diameter [nm] | | | | | | | |
| | Lattice distortion | 0.09 | 0.11 | 0.17 | 0.70 | 0.10 | 0.26 | 0.79 |
| | [%] | | | | | | | |
| pH of slurry | | 4.34 | 4.18 | 4.41 | 4.81 | 4.76 | 5.05 | 5.73 |
| Polishing | Polishing for 20 | 1635 | 1752 | 1807 | 2023 | 1748 | 1726 | 1620 |
| rate for | seconds | | | | | | | |
| silicon | [nm/min] | | | | | | | |
| oxide | Polishing for 50 | 1480 | 1676 | 1799 | 1794 | 1537 | 1300 | 1215 |
| | seconds | | | | | | | |
| | [nm/min] | | | | | | | |
| | Retention rate of | 90.5 | 95.7 | 99.6 | 88.7 | 87.9 | 75.3 | 75.0 |
| | polishing rate | | | | | | | |
| | [%] | | | | | | | |

1. A slurry comprising abrasive grains and water,
wherein the abrasive grains include cerium oxide particles,
a crystallite diameter of the cerium oxide particles is 17.0 nm or more, and
a lattice distortion of the cerium oxide particles is 0.10% or more.

2. The slurry according to claim 1,
wherein the crystallite diameter of the cerium oxide particles is 17.0 to 40.0 nm, and
the lattice distortion of the cerium oxide particles is 0.10 to 0.75%.

3. The slurry according to claim 1, wherein the crystallite diameter of the cerium oxide particles is 17.0 nm or more and less than 30.0 nm.

4. The slurry according to claim 1, wherein an average particle diameter of the abrasive grains is 200 to 400 nm.

5. The slurry according to claim 1, wherein a content of the abrasive grains is 0.01 to 10.00 mass %.

6. The slurry according to claim 1, wherein a pH is 1.00 to 7.00.

7. The slurry according to claim 1, wherein the slurry is used for polishing a surface to be polished containing silicon oxide.

8. A polishing method comprising a step of polishing a surface to be polished using the slurry according to claim 1.

9. The slurry according to claim 1, wherein a content of cerium oxide is 95 mass % or more based on the total mass of the abrasive grains contained in the slurry.

10. The slurry according to claim 1, wherein the crystallite diameter of the cerium oxide particles is 17.0 to 60.0 nm.

11. The slurry according to claim 1, wherein the crystallite diameter of the cerium oxide particles is 17.0 nm or more and less than 50.0 nm.

12. The slurry according to claim 1, wherein the crystallite diameter of the cerium oxide particles is 17.0 to 40.0 nm.

13. The slurry according to claim 1, wherein the lattice distortion of the cerium oxide particles is 0.10 to 1.00%.

14. The slurry according to claim 1, wherein the lattice distortion of the cerium oxide particles is 0.10 to 0.75%.

15. The slurry according to claim 1, wherein the lattice distortion of the cerium oxide particles is 0.10 to 0.30%.

16. The slurry according to claim 1, wherein an average particle diameter of the abrasive grains is 100 to 600 nm.

17. The slurry according to claim 1, wherein an average particle diameter of the abrasive grains is 200 to 300 nm.

18. The slurry according to claim 1, wherein the slurry further comprises a water-soluble polymer.

19. The slurry according to claim 18, wherein the water-soluble polymer includes polyglycerin.

20. The slurry according to claim 1, wherein a pH is 4.00 to 6.00.
